(19) United States
(12) Patent Application Publication
(10) Pub. No.: US 2020/0194285 A1
(43) Pub. Date: Jun. 18, 2020

(54) CATALYST USED FOR CATALYST-REFERRED ETCHING, PROCESSING PAD PROVIDED WITH CATALYST, AND CATALYST-REFERRED ETCHING DEVICE

(71) Applicants: EBARA CORPORATION, Tokyo (JP); OSAKA UNIVERSITY, Osaka (JP)

(72) Inventors: Atsuo Katagiri, Tokyo (JP); Itsuki Kobata, Tokyo (JP); Kazuto Yamauchi, Osaka (JP); Pho Van Bui, Osaka (JP)

(21) Appl. No.: 16/696,878

(22) Filed: Nov. 26, 2019

(30) Foreign Application Priority Data
Dec. 17, 2018 (JP) 235399/2018
May 20, 2019 (JP) 094425/2019

(51) Int. Cl. H01L 21/67; H01M 4/92; H01L 21/02

(52) U.S. Cl. CPC H01L 21/67075; H01L 21/02019; H01M 4/92

(57) ABSTRACT

A catalyst that is less poisoned is provided. The catalyst is used for catalyst-referred etching and includes: a first element for promoting etching of a processing object; and a second element for preventing an etching product generated by the etching from being adsorbed.

### CROSS-REFERENCE TO RELATED APPLICATION

This application is based upon and claims the benefit of priority of the prior Japanese Patent Application No. 2018-235399, filed on Dec. 17, 2018, and Japanese Patent Application No. 2019-94425, filed on May 20, 2019, the entire contents of which are incorporated herein by reference.

### TECHNICAL FIELD

The present application relates to a catalyst used for catalyst-referred etching, a processing pad provided with catalyst, and a catalyst-referred etching device.

### BACKGROUND ART

In manufacturing semiconductor devices, a Chemical Mechanical Polishing (CMP) device for polishing a substrate surface has been known. The CMP device has a polishing surface formed by attaching a polishing pad onto an upper surface of a polishing table. This CMP device presses a surface to be polished of a substrate, which is held by a top ring, against a polishing surface; and rotates the polishing table and the top ring while supplying slurry as a polishing liquid to the polishing surface. Accordingly, the polishing surface and the surface to be polished are relatively moved in a sliding manner, thereby polishing the surface to be polished.

In recent years, there have been a wide range of materials to be polished and polishing performances (in such as planarity and polishing damages, and further for productivity) of a planarization technique including CMP have been more severely required. In such a background, new planarization methods have been proposed and a catalyst-referred etching (hereinafter, CARE) method is also one of them. In the CARE method, a reactive species with a surface to be processed is generated from within a processing liquid only in the proximity to a catalyst material under the presence of processing liquid, and the catalyst material and the surface to be processed are brought close to or into contact with each other, thereby allowing selective generation of an etching reaction of the surface to be processed on a surface close to or in contact with the catalyst material. For example, on a surface to be processed which has a concave and convex, a convex part and a catalyst material are brought close to or in contact with each other so as to enable selective etching for the convex part, thereby allowing planarization of the surface to be processed. This CARE method originally has been proposed in planarization of next-generation substrate materials such as SiC and GaN that are not easy to planarize with high efficiency by CMP due to their chemical stabilities (for example, Japanese Patent Laid-Open No. 2008-121099, Japanese Patent Laid-Open No. 2008-136983, Japanese Patent Laid-Open No. 2008-166709, and Japanese Patent Laid-Open No. 2009-117782). However, it has been confirmed in recent years that silicon oxide or the like are also processable, and there is a possibility of application to semiconductor device materials such as a silicon oxide film and the like on a silicon substrate (for example, International Publication No. WO 2013/084934).

### SUMMARY OF INVENTION

### Technical Problem

In the CARE method, a chemical species derived from water adsorbed on a surface of a catalyst material continuously chemically reacts with a surface to be processed, thereby removing an element to be processed. At this point, if the removed element or a compound derived from the removed element remains on a surface of a catalyst, an active site of the catalyst may be deactivated. In the CARE method, deactivation of the active site of the catalyst may cause a phenomenon which decreases the removal rate of a surface to be processed in etching according to use time (number of times). Such a phenomenon is called “poisoning.” A significantly poisoned catalyst causes a significant decrease in the removal rate of the surface to be processed in etching with increasing number of use times; and therefore, it is difficult to apply the CARE method to manufacturing of semiconductor devices. It is one object of the present application to provide a catalyst that is less poisoned.

### Solution to Problem

A catalyst used for catalyst-referred etching is provided. This catalyst includes: a first element for promoting etching of a processing object; and a second element for preventing an etching product generated by the etching from being adsorbed.

### BRIEF DESCRIPTION OF DRAWINGS

FIG. 1 is a schematic plan view of a CARE device in one embodiment;

FIG. 2 is a side-surface view of the CARE device shown in FIG. 1;

FIG. 3 is a side-surface cross-sectional view that schematically shows a head structure in one embodiment;

FIG. 4 is a graph showing the removal rate of an SiO₂ film with respect to the number of processing times when CARE processing was performed by using each single metal of Ni and Ru as a catalyst;

FIG. 5 is a graph showing the removal rate of an SiO₂ film with respect to the number of processing times when CARE processing was performed by using each single metal of Cr and Ti as a catalyst.

FIG. 6 is a graph showing the removal rate of an SiO₂ film with respect to the number of processing times when CARE processing was performed by using each single metal of W, Al, and Cu as a catalyst;

FIG. 7 is a graph showing the removal rate of an SiO₂ film with respect to the number of processing times when CARE processing was performed by using each single metal of Pt, Rh, and Ir as a catalyst;

FIG. 8 is a graph showing the removal rate of an SiO₂ film with respect to the number of processing times when CARE processing was performed by using an alloy catalyst prepared by adding Mo to an Ni base;

FIG. 9 is a graph showing an average removal rate with respect to the content of Mo in an Ni—Mo alloy catalyst;

FIG. 10 is a graph showing the removal rate of an SiO₂ film with respect to the number of processing times when CARE processing was performed by using an alloy catalyst prepared by adding Cr to an Ni base;

FIG. 11 is a graph showing an average removal rate with respect to the content of Cr in an Ni—Cr alloy catalyst;

FIG. 12 is a graph showing the removal rate of an SiO₂ film with respect to the number of processing times when CARE processing was performed by using an alloy catalyst prepared by adding W to an Ni base;

FIG. 13 is a graph showing the removal rate of an SiO₂ film with respect to the number of processing times when CARE processing was performed by using an alloy catalyst prepared by adding Ti to an Ni base;

FIG. 14 is a graph showing the removal amount of an SiO₂ film with respect to the number of processing times when CARE processing was performed by using Ru alone and alloy catalysts respectively prepared by adding each of Ti, Zr, and V to an Ru base;

FIG. 15 is a graph showing the removal rates for each processing time on the assumption that a removal rate for each of the catalysts shown in FIG. 14 is 1.0 when the processing time is five minutes; and

FIG. 16 is a graph of the removal rates (RR) of an SiO₂ film with respect to the concentration of Ru in the alloy catalyst prepared by adding Ti to the Ru base, which shows a ratio of the removal rate at the time of fifth use (5th) to that at the time of first use (1st).

### DESCRIPTION OF EMBODIMENTS

Hereafter, embodiments of a catalyst used for catalyst-referred etching (CARE), processing pad provided with the catalyst, and catalyst-referred etching device (CARE device) of the present invention will be described with attached drawings. In the attached drawings, identical or similar elements are denoted by the same or similar reference signs; and in the description of each of the embodiments, a repeated explanation of the identical or similar elements may be omitted. In addition, characteristics indicated by each of the embodiments can be applied to the other embodiments as long as there is no mutual inconsistency.

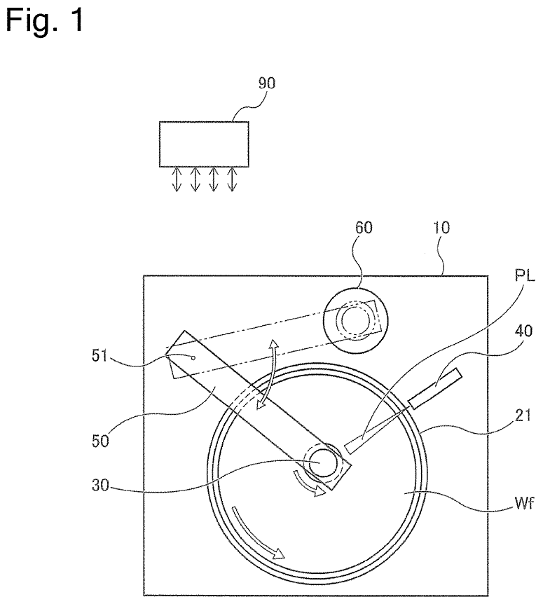

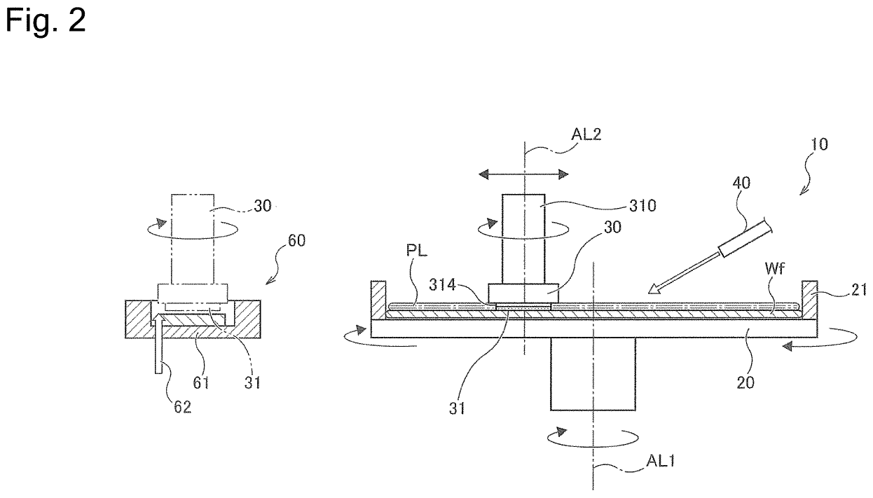

FIG. 1 is a schematic plan view of a CARE device 10 in one embodiment. FIG. 2 is a side-surface view of the CARE device 10 shown in FIG. 1. The CARE device 10 performs etching processing of a semiconductor device material (region to be processed) on a substrate by using a CARE method.

The CARE device 10 shown in FIG. 1 includes: a table 20 for holding a substrate; a head 30 for holding a catalyst; a nozzle 40 for supplying a processing liquid; a swing arm 50 for swinging the head 30; a conditioning part 60 for conditioning the catalyst; and a controller 90. The table 20 is constituted so as to hold a wafer Wf as a kind of the substrate. In one embodiment, the substrate can be an Si substrate and a surface to be processed can be an SiO₂ film formed on the Si substrate. In addition, in one embodiment, the surface to be processed may be another Si-based material such as an SiC substrate or an SiC film, or a metal film. In the embodiment shown in FIG. 1, the table 20 holds the wafer Wf so that a surface to be processed of the wafer Wf is directed upward.

In addition, in this embodiment, the table 20 includes, as a mechanism for holding the wafer Wf, a vacuum suction mechanism having a vacuum suction plate for vacuum suction of a rear surface of the wafer Wf (surface opposite to the surface to be processed). As a vacuum suction method, either of the following methods can be used: a point suction method using a suction plate having a plurality of suction holes, which are connected to a vacuum line, on a suction surface; and a surface suction method of sucking through a connection hole to a vacuum line provided within a groove (for example, concentrically shaped) which is included in the suction surface.

Further, for stabilization of a suction state, a backing material may be attached to a surface of the suction plate so as to suck the wafer Wf through this backing material. It is noted that a mechanism for holding the wafer Wf can be any publicly known mechanism. For example, it may be a clamp mechanism for clamping a front surface and rear surface of the wafer Wf at least at one part of a peripheral edge part of the wafer Wf; or may be a roller chuck mechanism for holding a side surface of the wafer Wf at least at one part of the peripheral edge part of the wafer Wf. The table 20 is constituted so as to be rotatable around an axial line AL1 by a driving unit motor, an actuator (not illustrated).

In addition, in the embodiment shown in FIG. 2, the table 20 includes a wall 21 that extends upward in a vertical direction over a whole circumferential direction outside a region for holding the wafer Wf. This allows the processing liquid PL to be held within a surface of the wafer, thereby allowing reduction in the consumption of the processing liquid PL.

In one embodiment, the processing liquid PL can be a basic chemical solution having a pH higher than 7. According to the embodiment, hydrolysis involved in the CARE method is promoted. In adjustment of the pH, chemical agents used therefor are not limited; however, a strong base is preferable in order to increase a processing speed. Further, a base not being adsorbed on a metal surface is preferable. In one embodiment, the processing liquid PL can be a chemical solution including sodium hydroxide (NaOH) or potassium hydroxide (KOH). Moreover, though the wall 21 in this figure is fixed to an outer periphery of the table 20, it can be constituted separately from the table. In this case, the wall 21 can be constituted so as to be movable up and down. The wall 21 which is movable up and down allows the holding amount of the processing liquid PL to be changed. In addition, for example, in cleaning a substrate surface after etching process, the wall 21 is lowered so as to allow a cleaning liquid to be efficiently discharged to an outside of the wafer Wf.

The head 30 in the embodiment shown in FIG. 1 and FIG. 2 includes a processing pad 314 for holding a catalyst 31 at its lower end. In this embodiment, the processing pad 314 and the catalyst 31 are smaller than the wafer Wf. That is, a projection area of the catalyst 31 when projection is performed from the catalyst 31 toward the wafer Wf is smaller than an area of the wafer Wf. In addition, the head 30 is constituted so as to be rotatable around an axial line AL2 by a driving unit motor, that is, an actuator (not illustrated). As shown in FIG. 2, the rotation axis AL1 of the table 20 and the rotation axis AL2 of the head 30 are deviated from each other. In addition, a motor and air cylinder for causing the catalyst 31 of the head 30 to slide while contacting the wafer Wf are included in the swing arm 50 (not illustrated).

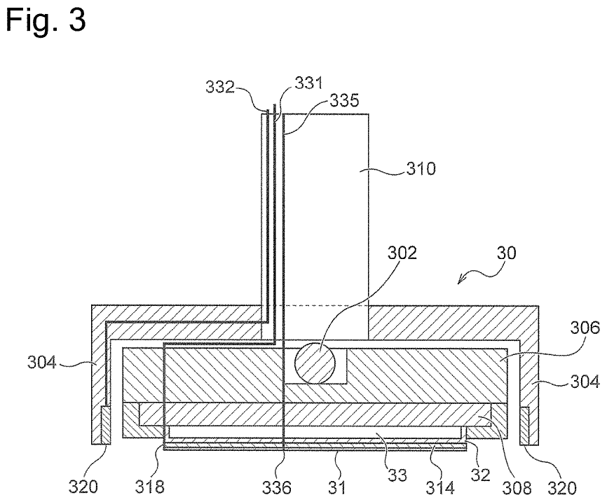

Next, the nozzle 40 is constituted so as to supply the processing liquid PL to the surface of the wafer Wf. It is noted that in the illustrated embodiment, the nozzle 40 is provided singly; however, it may be in plurality. In this case, a different processing liquid PL may be supplied from each of the nozzles. In addition, in cleaning the surface of the wafer Wf in the CARE device 10 after etching processing, a chemical liquid for cleaning and water may be supplied from the nozzles 40. Further, the nozzle 40 may be constituted so as to supply the processing liquid PL from the processing pad and a surface of the catalyst 31 via an inside of the head 30 (see FIG. 3).

Next, the swing arm 50 is constituted so as to be swingable around a rotation center 51 by a driving unit, that is, an actuator (not illustrated) and is also constituted so as to be movable up and down. At a tip end (an end part on an opposite side of the rotation center 51) of the swing arm 50, the head 30 is rotatably attached. It should be noted that in performing CARE processing, the rotation speed per unit time of the head 30 and the rotation speed per unit time of the table 20 are preferably different from each other. In addition, those rotation speeds per unit time are preferably coprime. Due to those characteristics of the rotation speeds, an uneven wear of the wafer Wf to be processed can be prevented.

FIG. 3 is a side-surface cross-sectional view that schematically shows a structure of the head 30 in one embodiment. In the embodiment shown in FIG. 3, the head 30 is connected to a shaft 310 via a gimbal mechanism 302 (for example, a spherical sliding bearing). Therefore, the head 30 including the catalyst 31 is rotatable around the gimbal mechanism 302 to some degree by following a surface of a substrate to be processed. In such a configuration, contact of only a part of the catalyst 31 with the substrate can be avoided, and the entire surface of the catalyst 31 can be brought into contact with or close to the substrate to be processed.

The shaft 310 is connected to the swing arm 50 as shown in FIG. 1. The head 30 is rotatable around the rotation axis AL2 by a rotation motor not illustrated. As shown in FIG. 3, the head 30 includes an outer peripheral member 304. The outer peripheral member 304 can have a substantially cylindrical shape with one end part closed.

At an inner side of the outer peripheral member 304, a head body 306 is arranged. At a lower side of the head body 306, a base plate 308 is arranged. The base plate 308 is detachably attached to the head body 306 with, for example, screws or the like. The base plate 308 is formed of, for example like a metal material, a material having a high rigidity equal to or higher than 50 GPa, preferably equal to or higher than 100 GPa with excellent machinability and surface finish, so as to provide a flat surface and prevent deformation. The base plate 308 can be formed of, for example, ceramic, stainless steel (SUS), or the like.

On a lower side surface of the base plate 308, an elastic member 32 is arranged. In the illustrated embodiment, the elastic member 32 is formed by an elastic film and inside the elastic member (elastic film) 32, a pressure chamber 33 is formed. The pressure chamber 33 is configured so that a fluid (for example, air or nitrogen gas) supplied to the pressure chamber 33 by a fluid source (not illustrated) is controlled so as to control a contact pressure between the region to be processed of the wafer Wf and the catalyst 31. As one example, the pressure of the pressure chamber 33 is controlled within a range of 0.1 psi to 3.0 psi. On a lower surface of the elastic film 32, a processing pad 314 is provided. The processing pad 314 is closely adhered to a lower surface of the elastic film 32 with, for example, a double-sided tape, an adhesive, welding, or the like. The processing pad 314 is preferably formed from a metal material in light of: maintaining surface roughness and shape accuracy still after application of the catalyst; maintaining strength against deformation by the elastic film 32; and applying a voltage to the catalyst. For example, the processing pad 314 can be formed from a metal foil having a thickness of 100 μm or less, such as an SUS foil. On a lower surface of the processing pad 314, the catalyst 31 is provided. Preferably, on a surface of the processing pad 314 for holding the catalyst 31, a groove (not illustrated) is provided. By providing the groove, the processing liquid PL used for CARE processing passes through an inside of the groove, thereby promoting the introduction and discharge of the processing liquid PL to between a surface of the catalyst and a surface of the wafer Wf as a processing object. A pattern of the groove provided on the surface of the processing pad 314 is freely selected; however, it may be, for example, a pattern of a groove radially extending from the surface of the processing pad 314, a pattern in which a plurality of concentrically shaped grooves are formed, or a combination of them.

As shown in FIG. 3, the head 30 includes a catalyst electrode 318 so as to allow application of a voltage to the catalyst 31. The catalyst electrode 318 is electrically connected to the catalyst 31 or processing pad 314. The catalyst electrode 318 is connected to wiring 331 through the head 30 and the shaft 310. Configuration is made such that when the base plate 308 is attached to the head body 306, the electric wiring 331 to the catalyst electrode 318 is established. In addition, on the outer peripheral member 304, a counter electrode 320 is provided. The counter electrode 320 is annularly shaped. The counter electrode 320 is connected to wiring 332 through the head 30 and the shaft 310. The catalyst electrode 318 and the counter electrode 320 have the wirings 331 and 332 installed through the head 30 and are connected to a power supply not illustrated. Therefore, the catalyst 31 and the counter electrode 320 can be electrically connected through the processing liquid PL. Application of a voltage to the catalyst 31 allows the active state of the catalyst 31 to be controlled, thus allowing the etching speed of the substrate Wf to be changed. It should be noted that though the counter electrode 320 is arranged in the head 30 in FIG. 3, it may be provided outside the head 30 not in the head 30 as long as the catalyst 31 and the counter electrode 320 are electrically connected through the processing liquid PL. Preferably, the catalyst electrode 318 and the counter electrode 320 are provided in a region in which the generation of gasses such as hydrogen and oxygen due to decomposition of the processing liquid does not occur.

In one embodiment, the head 30 includes a passage 335 for supplying the processing liquid PL, as shown in FIG. 3. The passage 335 extends through the shaft 310, the head body 306, the base plate 308, and the elastic member 32; and is connected to an opening 336 formed on the processing pad 314 and the catalyst 31. Therefore, the processing liquid PL can be supplied from the opening 336 onto the substrate Wf through the passage 335. In one embodiment, the processing liquid PL may be supplied from the nozzle 40 (FIGS. 1, 2), may be supplied from the head 30 through the passage 335, or may be supplied from the both.

In one embodiment, the catalyst 31 used for the CARE device 10 includes: a first element for promoting etching of the substrate as a processing object; and a second element for preventing an etching product generated by the etching from being adsorbed. The first element and the second element can be metals. For example, the catalyst 31 can be an alloy composed of the first element and second element of metals. As one example, the first element can be nickel (Ni) or ruthenium (Ru). As one example, the second element, being alloyed with the first element, is selected from elements capable of adjustment of a d-band center of the catalyst. As one example, the second element can be titanium (Ti), chromium (Cr), molybdenum (Mo), tungsten (W), vanadium (V), zirconium (Zr), aluminum (Al), iridium (Ir), rhodium (Rh), copper (Cu), platinum (Pt), or the like. In addition, the catalyst 31 using the first element and the second element can also be said to be: the first element that promotes etching and has a removal rate relatively higher than the second element; and the second element that does not cause a decrease in the removal rate when being singly used. Further, as one example, the catalyst 31 includes an alloy of: an element having an electron occupation rate of 50% or higher in a d orbital; and an element having an electron occupation rate of 50% or lower in a d orbital. Elements having the electron occupation rate of 50% or higher in a d orbital include elements with atomic numbers 26-30, 44-48, and 76-80. Elements having the electron occupation rate of 50% or lower in a d orbital include elements with atomic numbers 21-25, 39-43, and 72-75. In creating an alloy of a plurality of elements, the created alloy should have a band structure significantly different from any of the elements constituting the alloy; and therefore, elements adopted may be selected from elements whose energy levels are sufficiently separate from one another, that is, whose element numbers are sufficiently separate from one another. The alloy thus obtained has a wider band structure even in comparison with a single metal and therefore, it changes adsorption energy with a compound such as silicon oxide which has been removed from the substrate by the CARE method. In addition, when the catalyst 31 is an alloy, the content of the second element in the alloy is preferably from 5 atomic weight % (at. %) to 80 atomic weight %, and is further preferably from 10 atomic weight % to 50 atomic weight %.

In one embodiment, the catalyst 31 is formed as a film on, for example, a surface of the processing pad 314. For example, the catalyst 31 can be formed as a film on the surface of the processing pad 314 by a sputtering method, a chemical vapor deposition method, a vapor deposition method or the like. In using the sputtering method, a plurality of metals may be sputtered at a time or sputtering may be performed with a chip, frame or the like of one element installed on a target of another element, or an alloy film may be formed by sputtering alloy materials. Further, an alloy film may be formed by thermal treatment after laminating films of heterogeneous elements. Still further, the catalyst 31 may be formed on the processing pad 314 by other film forming methods such as electro plating and electroless plating. The thickness of the catalyst 31 is preferably about from 100 nm to several 10 μm. This is because when the catalyst comes into contact with the substrate and performs a relative motion, a degradation due to wear occurs and if the catalyst is extremely thin, the frequency of replacing the catalyst increases. In addition, the catalyst 31 which is plate-shaped may be fixed to the processing pad 314. Further, a layer of the catalyst 31 may be formed on the surface of the processing pad 314 by impregnating the processing pad 314 with a solution containing the catalyst.

### EXAMPLES

Catalyst-referred etching was performed for a substrate by using a plurality of alloy catalysts of different kinds and a single metal catalyst. First, a substrate including an SiO₂ film of 1000 nm on its surface was used as a processing object. The SiO₂ film was formed on an Si substrate by a chemical vapor deposition method. The diameter of the substrate was approximately 50 mm. As a processing liquid, 200 ml of 0.1 mol/L potassium hydroxide (KOH) solution was prepared. In addition, the KOH solution had a pH=13. Single metals used were nickel (Ni), ruthenium (Ru), chromium (Cr), titanium (Ti), tungsten (W), aluminum (Al), copper (Cu), platinum (Pt), rhodium (Rh), and iridium (Ir). In addition, as an alloy catalyst used, an alloy catalyst containing any of titanium (Ti), chromium (Cr), molybdenum (Mo), and tungsten (W) in nickel (Ni) (hereinafter, Ni—Ti alloy, Ni—Cr alloy, Ni—Mo alloy, Ni—W alloy) was created. Further, as an alloy catalyst used, an alloy catalyst containing any of titanium (Ti), zirconium (Zr), and vanadium (V) in ruthenium (Ru) (hereinafter, Ru—Ti alloy, Ru—Zr alloy, Ru—V alloy) was created. In the catalyst-referred etching, a head for holding each of the catalysts was slid in a state where both the substrate including the SiO₂ film and the catalyst were being brought into contact with each other while being rotated under the presence of a potassium hydroxide solution. In this example, time for single CARE processing was set to one minute. That is, in single processing, the catalyst and the SiO₂ film were being brought into contact for a minute while being relatively moved under the presence of the processing liquid. After completion of the processing, the substrate and the catalyst were quickly separated. In addition, after completion of the processing, the processing liquid was quickly removed and the surface of the substrate was cleaned with ultrapure water. After that, the substrate was quickly dried and the thickness of the SiO₂ film was measured by using an optical interference film thickness meter. Such CARE processing for one minute was performed five times for each of the catalysts. By measuring the film thickness of the SiO₂ film before and after the CARE processing, the removal amount and removal rate (Removal Rate) of the SiO₂ film in single processing can be obtained.

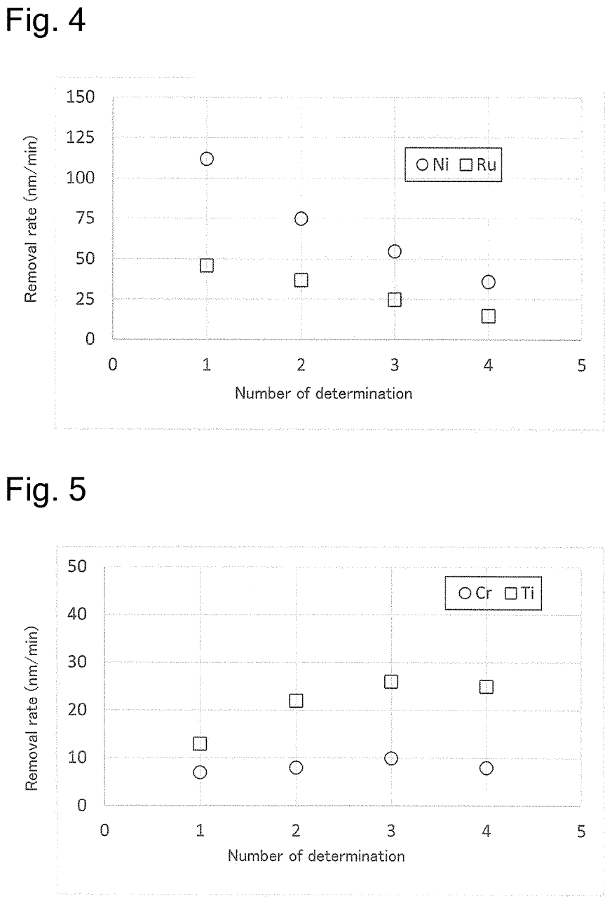

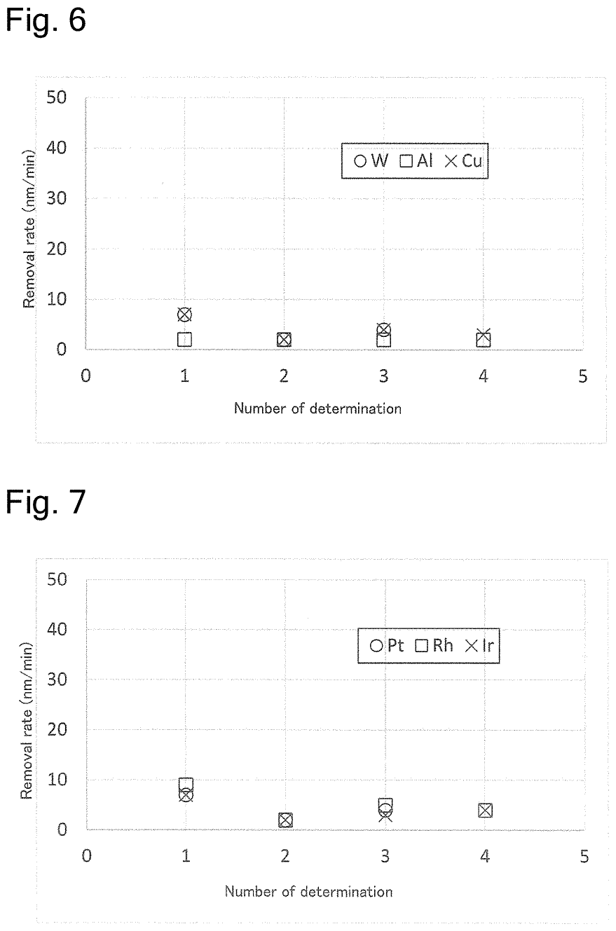

FIG. 4 to FIG. 7 show results of substrate processing using various single metals as a catalyst. In FIG. 4 to FIG. 7, a horizontal axis indicates the number of processing times (Number of determination), and a vertical axis indicates a removal rate (nm/min). FIG. 4 shows the removal rates of the SiO₂ film with respect to the number of processing times when CARE processing was performed by using each single metal of Ni and Ru as a catalyst. FIG. 5 shows the removal rates of the SiO₂ film with respect to the number of processing times when CARE processing was performed by using each single metal of Cr and Ti as a catalyst. FIG. 6 shows the removal rates of the SiO₂ film with respect to the number of processing times when CARE processing was performed by using each single metal of W, Al, and Cu as a catalyst. FIG. 7 shows the removal rates of the SiO₂ film with respect to the number of processing times when CARE processing was performed by using each single metal of Pt, Rh, and Ir as a catalyst.

As can be seen from FIG. 4 to FIG. 7, Ni and Ru exhibited higher removal rates than the other metals. As for Cr and Ti, the removal rates did not decrease regardless of an increase of the number of processing times. In addition, Cr and Ti exhibited somewhat higher removal rates than the other metals, though not as high removal rates as Ni and Ru. As for W, Al, Cu, Pt, Rh, and Ir, the removal rates decreased in second and subsequent processing in comparison with first processing, or the removal rates were originally low.

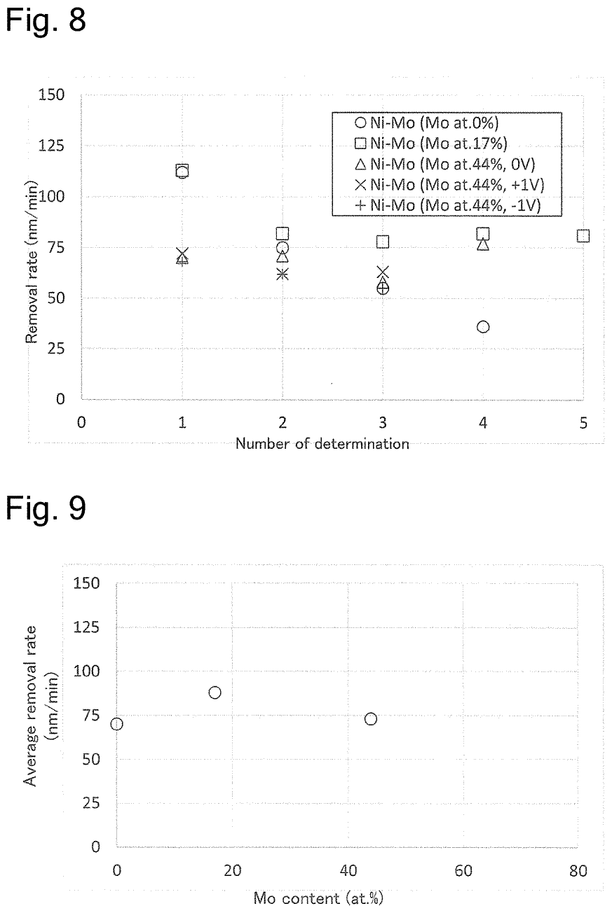

FIG. 8 and FIG. 9 show results of substrate processing using a single Ni catalyst and Ni—Mo alloy catalysts. FIG. 8 shows the removal rates of the SiO₂ film with respect to the number of processing times when CARE processing was performed by using an alloy catalyst prepared by adding Mo to an Ni base. In FIG. 8, a horizontal axis indicates the number of processing times and a vertical axis indicates a removal rate (nm/min). As shown in FIG. 8, when Ni was used alone as a catalyst (Mo at. 0%), the removal rate was monotonously decreasing with increasing number of processing times. On the other hand, as for the Ni—Mo alloy catalysts prepared by adding Mo to Ni, the removal rates in at least second and subsequent processing were relatively stable. Parts of the results shown in FIG. 8 were obtained by performing processing with an electric potential applied to the catalyst. As shown in FIG. 8, application of an electric potential to the catalyst changed the removal rate. FIG. 9 is a graph showing an average removal rate with respect to the content of Mo in the Ni—Mo alloy catalyst. As can be seen from FIG. 9, the average removal rate in using the Ni—Mo alloy as a catalyst was higher than in using Ni alone as a catalyst. In first processing, the removal rate in using Ni alone as a catalyst was higher than in using the Ni—Mo alloy as a catalyst; however, as for Ni alone, the removal rate decreased in second and subsequent processing; and therefore, on average, the removal rate in using the Ni—Mo alloy as a catalyst became higher and in addition, the removal rate was stabilized.

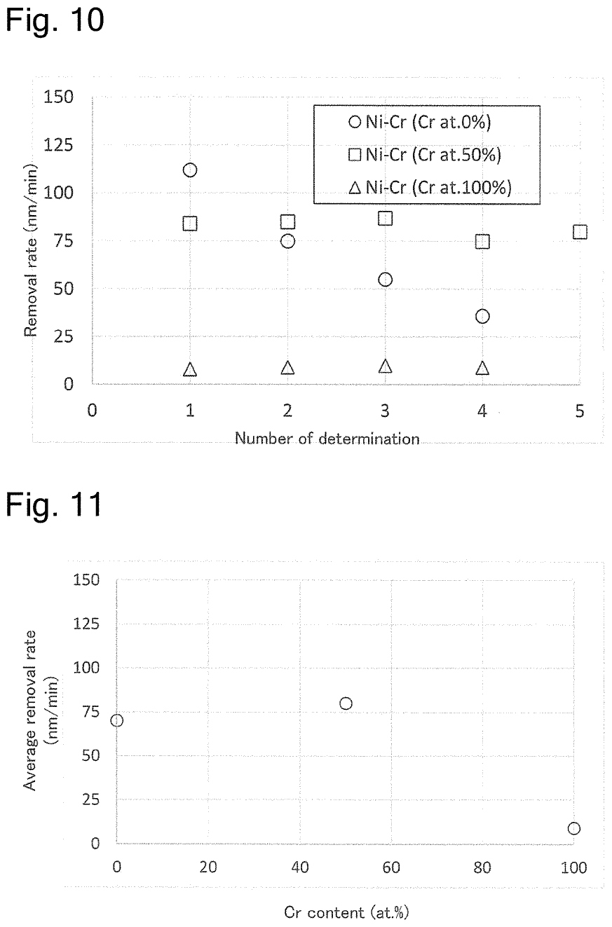

FIG. 10 and FIG. 11 show results of substrate processing using a single Ni catalyst and Ni—Cr alloy catalysts. FIG. 10 shows the removal rates of the SiO₂ film with respect to the number of processing times when CARE processing was performed by using an alloy catalyst prepared by adding Cr to an Ni base. In FIG. 10, a horizontal axis indicates the number of processing times and a vertical axis indicates a removal rate (nm/min). As shown in FIG. 10, when Ni was used alone as a catalyst (Cr at. 0%), the removal rate was monotonously decreasing with increasing number of processing times. On the other hand, as for the Ni—Cr alloy catalyst prepared by adding Cr to Ni, the removal rate in at least second and subsequent processing was relatively stable. In addition, when Cr was used alone as a catalyst (Cr at. 100%), the removal rate was also stable, but the removal rate was lower than in the case of the Ni—Cr alloy catalyst. FIG. 11 is a graph showing an average removal rate with respect to the content of Cr in the Ni—Cr alloy catalyst. As can be seen from FIG. 11, the average removal rate in using the Ni—Cr alloy as a catalyst was higher than in using Ni alone as a catalyst. In first processing, the removal rate in using Ni alone as a catalyst was higher than in using the Ni—Cr alloy as a catalyst; however, as for Ni alone, the processing rate decreased in second and subsequent processing; and therefore, on average, the removal rate became higher in using the Ni—Cr alloy as a catalyst and in addition, the removal rate was stabilized.

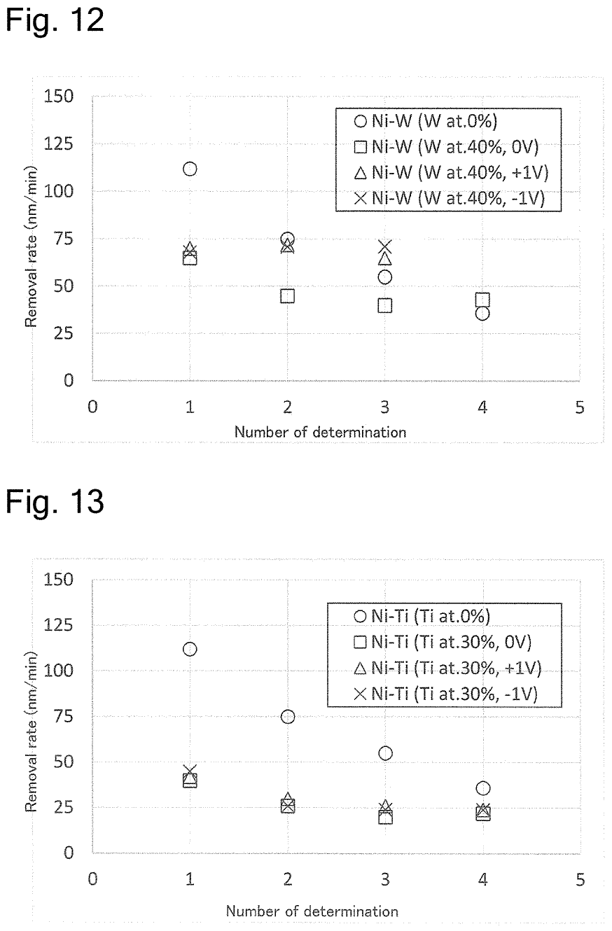

FIG. 12 shows results of substrate processing using a single Ni catalyst and an Ni—W alloy catalyst. FIG. 12 shows the removal rates of the SiO₂ film with respect to the number of processing times when CARE processing was performed by using an alloy catalyst prepared by adding W to an Ni base. In FIG. 12, a horizontal axis indicates the number of processing times and a vertical axis indicates a removal rate (nm/min). As shown in FIG. 12, when Ni was used alone as a catalyst (W at. 0%), the removal rate was monotonously decreasing with increasing number of processing times. On the other hand, as for the Ni—W alloy catalyst prepared by adding W to Ni, the removal rate in at least second and subsequent processing was relatively stable. Parts of the results shown in FIG. 12 were obtained by performing processing with an electric potential applied to the catalyst. As shown in FIG. 12, application of an electric potential to the catalyst improved the removal rate.

FIG. 13 shows results of substrate processing using a single Ni catalyst and an Ni—Ti alloy catalyst. FIG. 13 shows the removal rates of the SiO₂ film with respect to the number of processing times when CARE processing was performed by using an alloy catalyst prepared by adding Ti to an Ni base. In FIG. 13, a horizontal axis indicates the number of processing times and a vertical axis indicates a removal rate (nm/min). As shown in FIG. 13, when Ni was used alone as a catalyst (Ti at. 0%), the removal rate was monotonously decreasing with increasing number of processing times. On the other hand, as for the Ni—Ti alloy catalyst prepared by adding Ti to Ni, the removal rate in at least second and subsequent processing was relatively stable. Parts of the results shown in FIG. 13 were obtained by performing processing with an electric potential applied to the catalyst. As shown in FIG. 13, application of an electric potential to the Ni—Ti alloy catalyst did not change the removal rate so much.

FIG. 16 is a graph of the removal rate (RR) of the SiO₂ film with respect to the concentration t of Ru in the alloy catalyst prepared by adding Ti to an Ru base, which shows a ratio of the removal rate at the time of fifth use (5th) to that at the time of first use (1st). The graph in FIG. 16 shows that in the case of 100%, the removal rate did not decrease. It can be seen from the graph in FIG. 16 that a rate of decrease in the removal rate changed according to the content of Ru. In FIG. 16, approximately 100% is indicated when the content of Ru is approximately 66 at. %, and this shows that an optimal Ru content is approximately 66 at. %. However, when a decrease in the removal rate is allowed, an Ru content other than approximately 66 at. % may be selected; for example, when a decrease in a removal rate of approximately 20% is allowed, the Ru content may be from approximately 60 at. % to approximately 75 at. %.

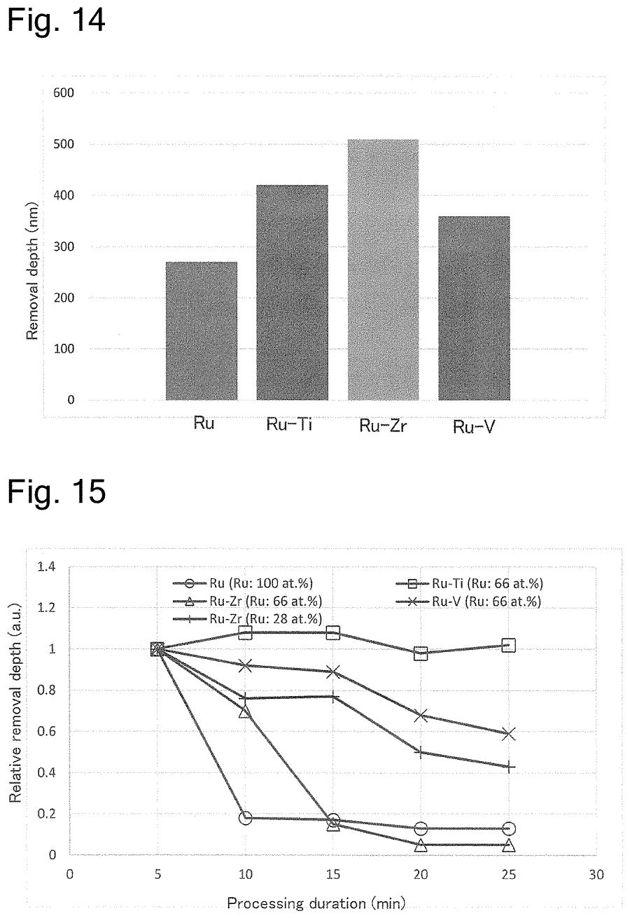

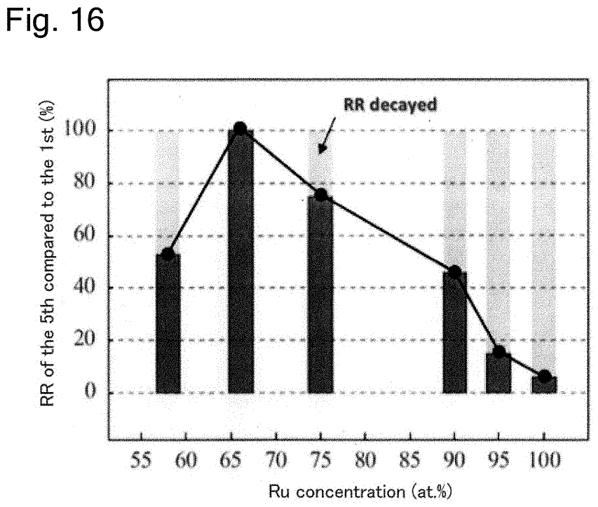

FIG. 14 shows the removal amount of the SiO₂ film with respect to the number of processing times when CARE processing was performed by using Ru alone and alloy catalysts respectively prepared by adding each of Ti, Zr, and V to an Ru base. In an example shown in FIG. 14, a KOH solution of pH=11 was used as a processing liquid and the processing time was five minutes. In FIG. 14, a horizontal axis indicates catalyst kinds and a vertical axis indicates a removal amount (nm). As shown in FIG. 14, the removal amount in using each of the Ru—Ti alloy, Ru—Zr alloy, and Ru—V alloy as a catalyst was more than in using Ru alone as a catalyst. FIG. 15 is a graph showing removal rates for each processing time on the assumption that the removal rate for each of the catalysts is 1.0 when the processing time is five minutes. As shown in FIG. 15, as for the Ru—Ti alloy catalyst, the removal rate did not decrease even when the processing time became longer. In addition, also as for the Ru—V alloy catalyst, the removal rate did not decrease as much as in the case of the single Ru catalyst.

As described above, in comparison with when using Ni alone as a catalyst, when each of the Ni—Mo alloy, Ni—Cr alloy, and Ni—W alloy, which are prepared by adding Mo, Cr, and W, respectively, is used as a catalyst, the removal rate is stable and a decrease in the removal rate of a surface to be processed due to, so-called, poisoning can be moderated or prevented. In addition, in comparison with when using Ni alone as a catalyst, when each of the Ni—Mo alloy and Ni—Cr alloy, which are prepared by adding Mo and Cr respectively, is used as a catalyst, the average removal rate becomes higher and therefore, in performing CARE processing for a plurality of substrates, the overall processing rate increases.

When Ni is used alone as a catalyst for substrate processing, it may occur that: a chemical species derived from water adsorbed on a catalyst surface causes a nucleophilic substitution reaction to Si on a surface of an oxide film, causing bonding with Si; and a silicon oxide or a compound derived from silicon remains on the catalyst surface, thereby causing the deactivation of a reactive site of the catalyst. However, it is considered that when an alloy prepared by adding Mo or Cr to Ni was used, the deactivation of the reactive site was reduced due to an effect of preventing a decrease in the removal rate of Mo or Cr, that is, an effect of making it difficult for a compound derived from silicon to remain.

In addition, when Ru is used alone as a catalyst for substrate processing, it may occur that: a chemical species derived from water adsorbed on a catalyst surface causes a nucleophilic substitution reaction to Si on a surface of an oxide film, causing bonding with Si; and a silicon oxide or a compound derived from silicon remains on the catalyst surface, thereby causing the deactivation of a reactive site of the catalyst. However, it is considered that when an alloy prepared by adding Ti, V, or Zr to Ru was used, the deactivation of the reactive site was reduced due to an effect of preventing a decrease in the removal rate of Ti, V, or Zr, that is, an effect of making it difficult for a compound derived from silicon to remain.

From such a viewpoint, it is preferable to select, as elements constituting an alloy catalyst, at least two elements from among transition metals; and it is preferable that at least one of the selected plurality of elements is an element having a relatively high removal rate for promoting etching and at least another one of the selected plurality of elements is an element not causing an decrease in the removal rate in attempting etching by itself.

From the present disclosure, at least the following technical ideas can be grasped. [Embodiment 1] According to Embodiment 1, a catalyst used for catalyst-referred etching is provided. This catalyst includes: a first element for promoting etching of a processing object; and a second element for preventing an etching product generated by the etching from being adsorbed and/or for preventing the first element from being altered.

[Embodiment 2] According to Embodiment 2, the catalyst of Embodiment 1 is an alloy or mixture including the first element and the second element.

[Embodiment 3] According to Embodiment 3, the first element in the catalyst of Embodiment 2 is nickel (Ni) or ruthenium (Ru).

[Embodiment 4] According to Embodiment 4, the second element in the catalyst of any one of Embodiment 1 to Embodiment 3 is an element such that the amount of reduction in the removal rate with processing time in a case where catalyst-referred etching processing is performed using the second element alone as a catalyst is less than the amount of reduction in the removal rate with processing time in a case where catalyst-referred etching processing is performed using the first element alone as a catalyst.

[Embodiment 5] According to Embodiment 5, the second element in the catalyst of any one of Embodiment 1 to Embodiment 4 is selected from a group consisting of aluminum, titanium, vanadium, chromium, copper, molybdenum, rhodium, tungsten, iridium, and platinum.

[Embodiment 6] According to Embodiment 6, a head used for catalyst-referred etching is provided. This head includes a processing pad and a surface of the processing pad has the catalyst according to any one of claims 1 to 5.

[Embodiment 7] According to Embodiment 7, the processing pad of the head of Embodiment 6 includes an inelastic member and the catalyst is arranged on the inelastic member.

[Embodiment 8] According to Embodiment 8, the head of Embodiment 7 includes an elastic member for defining a pressure chamber and the inelastic member is attached to the elastic member.

[Embodiment 9] According to Embodiment 9, the head of any one of Embodiment 6 to Embodiment 8 includes an opening for supplying a processing liquid onto a processing object.

[Embodiment 10] According to Embodiment 10, a catalyst-referred etching method is provided. This catalyst-referred etching method includes the steps of: preparing the catalyst according to any one of Embodiment 1 to Embodiment 5; and bringing the catalyst into contact with or close to a processing object under the presence of a processing liquid.

[Embodiment 11] According to Embodiment 11, the processing liquid in the catalyst-referred etching method of Embodiment 10 is basic.

[Embodiment 12] According to Embodiment 12, the catalyst-referred etching method of Embodiment 10 or Embodiment 11 includes a step of applying a voltage to the catalyst.

[Embodiment 13] According to Embodiment 13, the catalyst-referred etching method of any one of Embodiment 10 to Embodiment 12 includes a step of making the catalyst and the processing object perform a relative motion while being brought into contact with or close to each other.

### REFERENCE SIGNS LIST

10 CARE device
20 table
21 wall
30 head
31 catalyst
32 elastic member
33 pressure chamber
40 nozzle
50 swing arm
90 controller
314 processing pad
318 catalyst electrode
320 counter electrode
335 passage
336 opening
PL processing liquid
Wf wafer

What is claimed is:

1. A catalyst used for catalyst-referred etching, comprising:
a first element for promoting etching of a processing object; and
a second element for preventing an etching product generated by the etching from being adsorbed and/or for preventing the first element from being altered.

2. The catalyst according to claim 1, wherein
the catalyst is an alloy or mixture including the first element and the second element.

3. The catalyst according to claim 2, wherein
the first element is nickel (Ni) or ruthenium (Ru).

4. The catalyst according to claim 1, wherein
the second element is an element such that a second reduction amount is less than a first reduction amount, the first reduction amount being an amount of reduction in a removal rate with processing time in a case where catalyst-referred etching processing is performed using the first element alone as a catalyst, the second reduction amount being an amount of reduction in a removal rate with processing time in a case where catalyst-referred etching processing is performed using the second element alone as a catalyst.

5. The catalyst according to claim 1, wherein
the second element is selected from a group consisting of aluminum, titanium, vanadium, chromium, copper, molybdenum, rhodium, tungsten, iridium, and platinum.

6. A head used for catalyst-referred etching, comprising:
a processing pad; wherein
a surface of the processing pad has the catalyst according to claim 1.

7. The head according to claim 6, wherein
the processing pad has an inelastic member; and
the catalyst is arranged on the inelastic member.

8. The head according to claim 7, wherein
the head has an elastic member for defining a pressure chamber; and
the inelastic member is attached to the elastic member.

9. The head according to claim 6, wherein
the head has an opening for supplying a processing liquid onto a processing object.

10. A catalyst-referred etching method, comprising the steps of:
preparing the catalyst according to claim 1; and
bringing the catalyst into contact with or close to a processing object under a presence of a processing liquid.

11. The catalyst-referred etching method according to claim 10, wherein
the processing liquid is basic.

12. The catalyst-referred etching method according to claim 10, comprising the step of:
applying a voltage to the catalyst.

13. The catalyst-referred etching method according to claim 10, comprising the step of:
making the catalyst and processing object perform a relative motion while being brought into contact with or close to each other.
